(19) United States
(12) Patent Application Publication
(10) Pub. No.: US 2026/0293356 A1
(43) Pub. Date: Sep. 24, 2026

(54) LIGHT DETECTION DEVICE

(71) Applicant: SONY SEMICONDUCTOR SOLUTIONS CORPORATION, KANAGAWA (JP)

(72) Inventors: TAKUYA NAKANO, KUMAMOTO (JP); KOTA MARUYAMA, KUMAMOTO (JP)

(21) Appl. No.: 19/477,504

(22) PCT Filed: Mar. 25, 2024
(86) PCT No.: PCT/JP2024/011712

§ 371 Date: Oct. 22, 2025

(30) Foreign Application Priority Data
May 12, 2023 (JP) 2023-079299

(51) Int. Cl. H10F 39/00

(52) U.S. Cl. CPC H10F 39/811; H10F 39/809

(57) ABSTRACT

Provided is a light detection device capable of improving the bondability between a bump electrode and a pad electrode. The light detection device includes: a first substrate portion including a pixel region and a peripheral region located around the pixel region; and a semiconductor chip including a bump electrode. The first substrate portion includes a first semiconductor layer, a photoelectric conversion section provided in the first semiconductor layer in the pixel region, a pad electrode provided in one surface side of the first semiconductor layer in the peripheral region, and an insulating film provided in the one surface side of the first semiconductor layer. The insulating film is provided with a pad opening that opens a portion above the pad electrode. The bump electrode is bonded to the pad electrode in a state of being separated from a peripheral edge portion of an opening end of the pad opening.

### TECHNICAL FIELD

The present disclosure relates to a light detection device.

### BACKGROUND ART

A solid-state imaging device has been proposed in which a pixel section that photoelectrically converts incident light and a peripheral circuit section that performs signal processing are divided into separate elements (a sensor element and a logic element), and for example, the logic element is flip-chip mounted in a region outside the pixel section of the sensor element which includes the pixel section (see, for example, Patent Documents 1 and 2).

### CITATION LIST

### Patent Document

Patent Document 1: Japanese Patent Application Laid-Open No. 2016-171297

Patent Document 2: Japanese Patent Application Laid-Open No. 2020-080363

### SUMMARY OF THE INVENTION

### Problems to be Solved by the Invention

In chip on wafer (CoW) bonding which is one form of flip-chip mounting, for example, a bump electrode provided on a chip is bonded to a pad electrode provided on a wafer.

On the wafer side, the depth of a pad opening that opens a portion above the pad electrode tends to increase in height and increase in depth due to a light collection characteristic requirement and a wiring structure arrangement. When the depth of the pad opening increases, it becomes difficult to bring a tip of the bump electrode into contact with a front surface of the pad electrode located at the bottom of the pad opening in the initial stage of the bonding process of bonding the bump electrode to the pad electrode, and there is a possibility that the bondability between the bump electrode and the pad electrode decreases.

The present disclosure has been made in view of such circumstances, and an object thereof is to provide a light detection device capable of improving the bondability between a bump electrode and a pad electrode.

### Solutions to Problems

A light detection device according to one aspect of the present disclosure includes: a first substrate portion including a pixel region and a peripheral region located around the pixel region; and a semiconductor chip including a bump electrode. The first substrate portion includes a first semiconductor layer, a photoelectric conversion section provided in the first semiconductor layer in the pixel region, a pad electrode provided in one surface side of the first semiconductor layer in the peripheral region, and an insulating film provided in the one surface side of the first semiconductor layer. The insulating film is provided with a pad opening that opens a portion above the pad electrode. The bump electrode is bonded to the pad electrode in a state of being separated from a peripheral edge portion of an opening end of the pad opening.

With this configuration, it is possible to prevent the bump electrode from being formed in a distorted shape along the peripheral edge portion of the opening end of the pad opening.

As a result, it is possible to suppress generation of stress (internal stress) inside the bump electrode, and it is possible to suppress generation of a crack in the bump electrode due to the internal stress.

In addition, in a case of melt-bonding the bump electrode to the pad electrode, it becomes easy to expand the bump electrode in the molten state in the horizontal direction parallel to the pad electrode without bringing the bump electrode into contact with a side surface of the pad opening.

As a result, the height of the bump electrode can be reduced, and the physical distance between the semiconductor chip and the pad electrode can be reduced.

From the above, it is possible to improve the bondability between the bump electrode and the pad electrode.

### BRIEF DESCRIPTION OF DRAWINGS

FIG. 1 is a cross-sectional view illustrating a configuration example of an imaging device according to a first embodiment of the present disclosure.

FIG. 2 is a plan view illustrating a configuration example of the imaging device according to the first embodiment of the present disclosure.

FIG. 3A is a cross-sectional view illustrating a configuration example of a pad electrode of a sensor element, a bump electrode in an initial state, and a peripheral portion thereof, which are a part of the imaging device according to the first embodiment of the present disclosure.

FIG. 3B is a cross-sectional view illustrating a configuration example of the pad electrode of the sensor element, the bump electrode after bonding, and the peripheral portion thereof, which are a part of the imaging device according to the first embodiment of the present disclosure.

FIG. 4 is a plan view illustrating a configuration example (part 1) of a pad opening of the sensor element and a peripheral portion thereof according to the first embodiment of the present disclosure.

FIG. 5 is a plan view illustrating a configuration example (part 2) of the pad opening of the sensor element and the peripheral portion thereof according to the first embodiment of the present disclosure.

FIG. 6 is a cross-sectional view illustrating a first modification of the imaging device according to the first embodiment of the present disclosure.

FIG. 7 is a cross-sectional view illustrating a second modification of the imaging device according to the first embodiment of the present disclosure.

FIG. 8A is a cross-sectional view illustrating a configuration example of a pad electrode of a sensor element, a bump electrode 55 in an initial state, and a peripheral portion thereof, which are a part of an imaging device according to a second embodiment of the present disclosure.

FIG. 8B is a cross-sectional view illustrating a configuration example of the pad electrode of the sensor element, the bump electrode after bonding, and the peripheral portion thereof, which are a part of the imaging device according to the second embodiment of the present disclosure.

FIG. 9 is a cross-sectional view illustrating a configuration example of a pad opening according to the second embodiment of the present disclosure.

FIG. 10 is a plan view illustrating a configuration example of the pad opening of the sensor element and the peripheral portion thereof according to the second embodiment of the present disclosure.

FIG. 11 is a plan view illustrating a first modification of the imaging device according to the second embodiment of the present disclosure.

FIG. 12 is a plan view illustrating a second modification of the imaging device according to the second embodiment of the present disclosure.

FIG. 13 is a plan view illustrating a third modification of the imaging device according to the second embodiment of the present disclosure.

FIG. 14 is a plan view illustrating a fourth modification of the imaging device according to the second embodiment of the present disclosure.

FIG. 15 is a cross-sectional view illustrating a fifth modification of the imaging device according to the second embodiment of the present disclosure.

FIG. 16 is a plan view illustrating the fifth modification of the imaging device according to the second embodiment of the present disclosure.

FIG. 17 is a cross-sectional view illustrating a sixth modification of the imaging device according to the second embodiment of the present disclosure.

FIG. 18 is a cross-sectional view illustrating a seventh modification of the imaging device according to the second embodiment of the present disclosure.

FIG. 19 is a cross-sectional view illustrating an eighth modification of the imaging device according to the second embodiment of the present disclosure.

FIG. 20 is a cross-sectional view illustrating a configuration example of a pad electrode of a sensor element, a bump electrode in an initial state, and a peripheral portion thereof, which are a part of an imaging device according to a third embodiment of the present disclosure.

FIG. 21 is a plan view illustrating a configuration example of a pad opening of the sensor element and a peripheral portion thereof, which are a part of the imaging device according to the third embodiment of the present disclosure.

FIG. 22 is a plan view illustrating a first modification of the imaging device according to the third embodiment of the present disclosure.

FIG. 23 is a plan view illustrating a second modification of the imaging device according to the third embodiment of the present disclosure.

FIG. 24 is a plan view illustrating a third modification of the imaging device according to the third embodiment of the present disclosure.

FIG. 25 is a plan view illustrating a fourth modification of the imaging device according to the third embodiment of the present disclosure.

FIG. 26 is a first application example of the present disclosure, and is a diagram illustrating an overall configuration of the imaging device.

FIG. 27 is a second application example of the present disclosure, and is a diagram illustrating a schematic configuration of an electronic apparatus (camera).

FIG. 28 is a block diagram illustrating a schematic configuration example of a vehicle control system, which is an example of a mobile body control system to which the technology according to the present disclosure can be applied.

FIG. 29 is a diagram illustrating an example of an installation position of imaging sections.

### MODE FOR CARRYING OUT THE INVENTION

Hereinafter, embodiments of the present disclosure will be described with reference to the drawings. In the illustration of the drawings referred to in the following description, the same or similar portions are denoted by the same or similar reference signs. It should be noted that the drawings are schematic, and a relationship between a thickness and a planar dimension, a ratio of the thicknesses between respective layers, and the like are different from actual ones. Therefore, specific thicknesses and dimensions should be determined in consideration of the following description. In addition, it is needless to say that the drawings include portions having different dimensional relationships and ratios.

Definitions of directions such as up and down in the following description are merely definitions for convenience of description, and do not limit the technical idea of the present disclosure. For example, it is a matter of course that when an object is observed by rotating the object by 90°, the up and down are converted into and read as left and right, and when the object is observed by rotating the object by 180°, the up and down are inverted and read.

In the following description, there will be a case where directions are described using terms such as an X-axis direction, a Y-axis direction, and a Z-axis direction. For example, the Z-axis direction is a thickness direction of imaging devices 1, 1A, and 1B described later. The X-axis direction and the Y-axis direction are directions orthogonal to the Z-axis direction. The X-axis direction, the Y-axis direction, and the Z-axis direction are orthogonal to each other.

In the following description, plan view means viewing from the Z-axis direction.

### First Embodiment

### Overall Configuration of Imaging Device

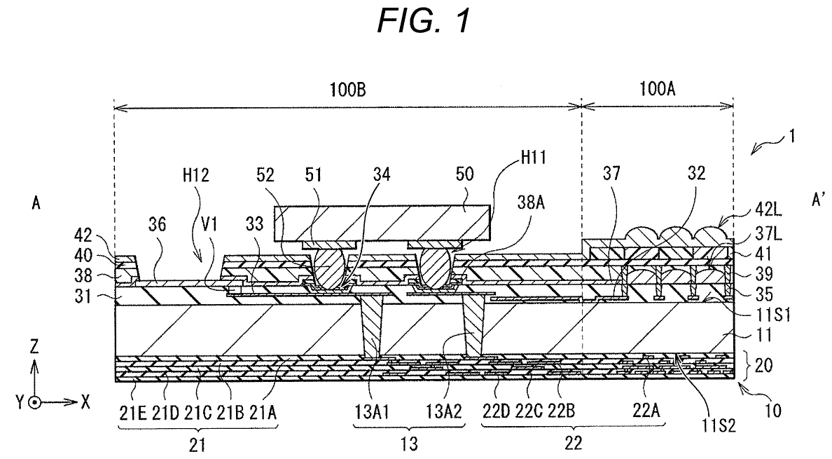

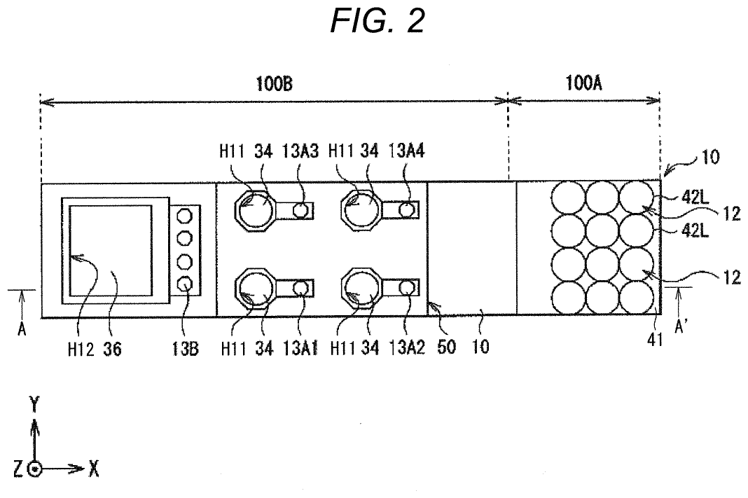

FIG. 1 is a cross-sectional view illustrating a configuration example of the imaging device 1 according to a first embodiment of the present disclosure. FIG. 2 is a plan view illustrating a configuration example of the imaging device 1 according to the first embodiment of the present disclosure.

Note that FIG. 1 illustrates a cross section of the plan view illustrated in FIG. 2 taken along line A-A′. In addition, in FIG. 2, a logic chip 50 illustrated in FIG. 1 is not illustrated.

The imaging device 1 illustrated in FIGS. 1 and 2 is an example of a “light detection device” of the present disclosure. The imaging device 1 is, for example, a back-surface irradiation type (back-surface light receiving type) complementary metal oxide semiconductor (CMOS) image sensor, and is a laminated type imaging device in which the logic chip 50 (an example of a “semiconductor chip” of the present disclosure) including various kinds of signal processing circuits that perform signal processing is flip-chip mounted on a sensor element 10 (an example of a “first substrate portion” of the present disclosure).

### Sensor Element

As illustrated in FIGS. 1 and 2, the sensor element 10 includes a pixel region (that is, the light receiving region) 100A in which a plurality of photoelectric conversion sections 12 is two-dimensionally arranged on a silicon substrate 11 (an example of a “first semiconductor layer” of the present disclosure), and a peripheral region 100B provided around the pixel region 100A. In the sensor element 10, a back surface 11S1 (an example of “one surface” of the present disclosure) of the silicon substrate 11 is a light incident surface, and a multilayer wiring layer 20 is provided on a front surface 11S2 of the silicon substrate 11. The logic chip 50 is mounted via a pad electrode 34 (an example of a “pad electrode” of the present disclosure) provided on the back surface 11S1 side of the silicon substrate 11 in the peripheral region 100B of the sensor element 10.

The pad electrode 34 is electrically connected to, for example, a wiring 22 constituting a multilayer wiring layer 20 provided on the front surface 11S2 side of the silicon substrate 11 via the wiring 33 (an example of a “wiring” of the present disclosure) provided on the back surface 11S1 of the silicon substrate 11 and a through via 13 penetrating the silicon substrate 11.

In the imaging device 1, a pad electrode 36 used for connection with an external substrate (not illustrated) is further provided on the back surface 11S1 side of the silicon substrate 11 in the peripheral region 100B of the sensor element 10. The pad electrode 34 and the pad electrode 36 are electrically connected via, for example, only the wiring 33 provided on the back surface 11S1 of the silicon substrate 11.

Alternatively, although not illustrated in FIG. 1, the pad electrode 34 and the pad electrode 36 may be electrically connected by, for example, the wiring 33 provided on the back surface 11S1 of the silicon substrate 11, the through via 13 penetrating the silicon substrate 11, and the wiring 22 constituting the multilayer wiring layer 20 provided on the front surface 11S2 side of the silicon substrate 11.

### Pixel Region

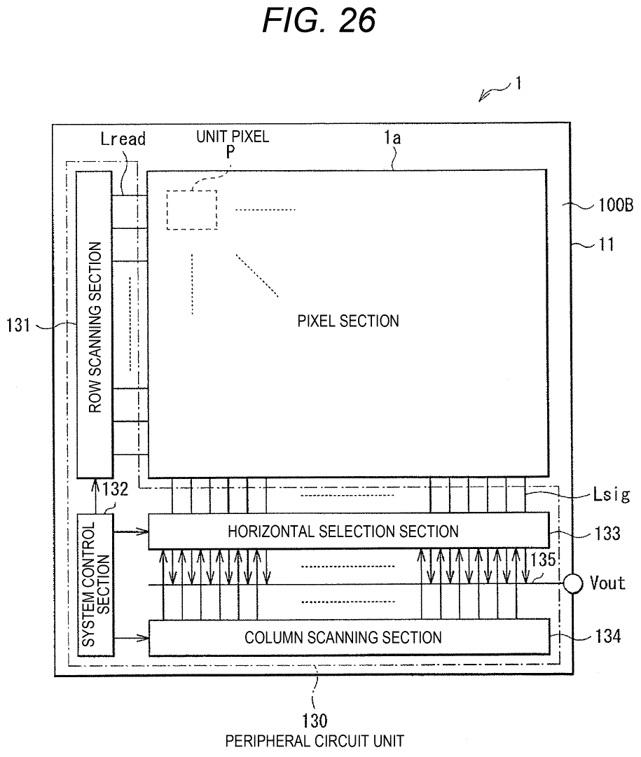

In the pixel region 100A, the photoelectric conversion section 12, which selectively detects light in wavelength regions different from each other to perform photoelectric conversion, is provided for each unit pixel P (see, for example, FIG. 26 described later). The photoelectric conversion section 12, which is an n-type semiconductor region, for example, provided in a thickness direction (Z-axis direction in FIG. 1) of the silicon substrate 11, is constituted by a photodiode (PD) for pn junction with a p-type semiconductor region provided on the front surface 11S2 of the silicon substrate 11. For example, the photoelectric conversion section 12 is embedded in the silicon substrate 11 for each unit pixel P.

The silicon substrate 11 is further provided with, in the vicinity of the front surface 11S2, a charge accumulation section that accumulates signal charges generated in the photoelectric conversion section 12, and a transfer transistor (TG) that transfers the signal charges to the charge accumulation section. In the vicinity of the front surface 11S2 of the silicon substrate 11, for example, a reset transistor (RST), an amplification transistor (AMP), a selection transistor (SEL), and the like are provided together with the transfer transistor (TG).

Such a transistor is, for example, a metal oxide semiconductor field effect transistor (MOSEFT), and constitutes a circuit for each unit pixel P. Each circuit may have a three-transistor configuration including, for example, the transfer transistor (TG), the reset transistor (RST), and the amplification transistor (AMP), or may have a four-transistor configuration including the selection transistor (SEL) in addition to the transistors mentioned above. The transistors other than the transfer transistor (TG) may be shared between the pixels.

In the pixel region 100A, for example, an interlayer insulating film 31 (an example of an “insulating film” in the present disclosure), an inner lens 37L, a flattening layer 38, a protective layer 40, a color filter 41, and an on-chip lens 42L are provided in this order on the light receiving surface (back surface 11S1) side of the silicon substrate 11. Each of the inner lens 37L, the color filter 41, and the on-chip lens 42L is arranged to face the photoelectric conversion section 12 provided in each unit pixel P, for example.

Each of the interlayer insulating film 31, inner lens 37L, flattening layer 38, protective layer 40, color filter 41, and on-chip lens 42L is constituted by, for example, a material having transparency. Specifically, for example, it is constituted by a single-layer film including any of silicon nitride (SiN), silicon oxynitride (SiON), and the like, or a laminated film including two or more kinds of silicon nitride (SiN), silicon oxynitride (SiON), and the like.

Pixel isolation sections 35 and 39 are provided between each of the unit pixels P. The pixel isolation section 35 is provided in the interlayer insulating film 31, the pixel isolation section 39 is provided in the flattening layer 38, and the pixel isolation sections 35 and 39 are connected to each other. The pixel isolation sections 35 and 39 are formed using, for example, a material having a light shielding property such as tungsten (W).

### Peripheral Region

In the peripheral region 100B, for example, the interlayer insulating film 31, an inner lens layer 37, the flattening layer 38, the protective layer 40, and an on-chip lens layer 42 are laminated in this order on the back surface 11S1 side of the silicon substrate 11. The inner lens layer 37 and the on-chip lens layer 42 extend from the inner lens 37L and the on-chip lens 42L, respectively, provided in the pixel region 100A.

In the peripheral region 100B, for example, four pad electrodes 34 (two of them are illustrated in FIG. 1) for mounting the logic chip 50 on the sensor element 10 and, for example, one pad electrode 36 to be used for connection with an external substrate are provided.

Although details will be described later, the pad electrodes 34 and 36 are provided, for example, between the interlayer insulating film 31 and the flattening layer 38. In the interlayer insulating film 31, for example, the wiring 33 that electrically connects the pad electrode 34 and the pad electrode 36 is provided. Furthermore, in the interlayer insulating film 31, for example, a light-shielding film 32 including a conductive material having a light shielding property such as tungsten (W) may be provided between the pixel region 100A and the peripheral region 100B.

The silicon substrate 11 is provided with, for example, the through via 13 penetrating between the back surface 11S1 and the front surface 11S2. The through via 13 is provided for each of the pad electrodes 34 and 36, for example. For example, as illustrated in FIG. 2, the four pad electrodes 34 are connected to the respective through vias 13A1, 13A2, 13A3, and 13A4 via the wiring 33.

The wiring 33 is constituted by, for example, copper (Cu) or a Cu alloy. The thickness of the wiring 33 is, for example, 50 nm or more and 300 nm or less. Since the wiring 33 is constituted by Cu or a Cu alloy, it is possible to make the thickness sufficiently thin (for example, make it to 1/10 or less) as compared with a case of being constituted by aluminum (Al) or an Al alloy. As a result, the height of the sensor element 10 can be reduced, and eventually, the height of the imaging device 1 can be reduced.

Note that, in the embodiment of the present disclosure, the material constituting the wiring 33 is not limited to Cu or a Cu alloy. For example, if the thickness is not considered, the wiring 33 may be constituted by Al or an Al alloy.

The insulating film 38A, the inner lens layer 37, the flattening layer 38, the protective layer 40, and the on-chip lens layer 42, which are on the pad electrode 34, are provided with a pad opening H11 (an example of a “pad opening” of the present disclosure) for exposing the pad electrode 34.

The pad electrode 36 is used for connection with the external substrate, and is provided on the interlayer insulating film 31, for example. The inner lens layer 37, the flattening layer 38, the protective layer 40, and the on-chip lens layer 42, which are on the pad electrode 36, are provided with an opening H12 for exposing the pad electrode 36.

Moreover, for example, the pad electrode 36 is preferably provided at a height same as that of the pad electrode 34. Here, for example, “same” is assumed to be a difference in height between the lower surfaces of the pad electrode 34 and the pad electrode 36 is less than or equal to the thickness of the insulating layer provided with one of the pad electrode 34 and the pad electrode 36. As a result, processing of the pad electrode 34 and the pad electrode 36 is facilitated.

On the front surface 11S2 of the silicon substrate 11, the multilayer wiring layer 20 including an insulating layer 21 and the wiring 22 is provided. The insulating layer 21 includes, for example, insulating layers 21A, 21B, 21C, 21D, and 21E. The wiring 22 includes wirings 22A, 22B, 22C, and 22D provided between the respective ones of the insulating layers 21A, 21B, 21C, 21D, and 21E. The through via 13 penetrating the silicon substrate 11 has one end connected to the wiring 33, which is connected to the pad electrode 34 provided on the back surface 11S1 side of the silicon substrate 11, and has the other end connected to the wiring 22A provided on the front surface 11S2 side of the silicon substrate 11.

### Logic Chip

The logic chip 50 is formed with various kinds of signal processing circuits that perform signal processing. In the logic chip 50, for example, a bump electrode 55 (an example of a “bump electrode” of the present disclosure) is provided on a lower surface. In the present embodiment, the bump electrode 55 of the logic chip 50 is bonded onto the plurality of pad electrodes 34 provided on the back surface 11S1 side of the silicon substrate 11 and exposed through the respective ones of the plurality of pad openings H11.

### Configuration Example of Pad Electrode, Bump Electrode, and Peripheral Portion Thereof

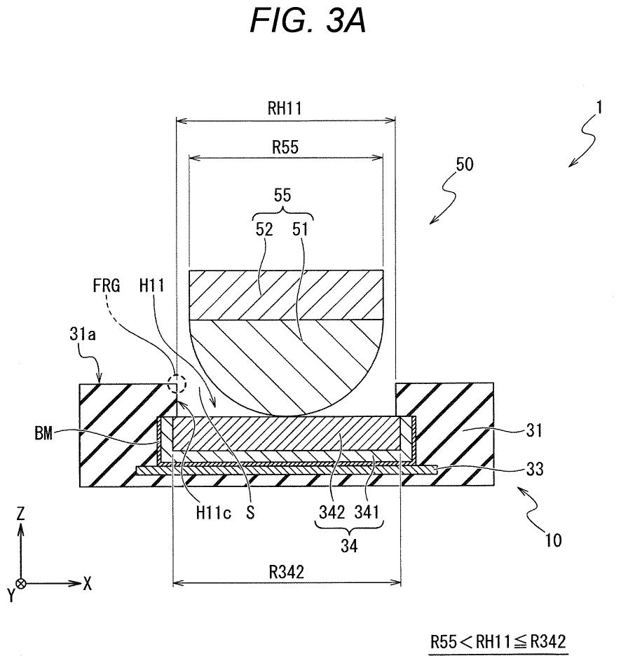

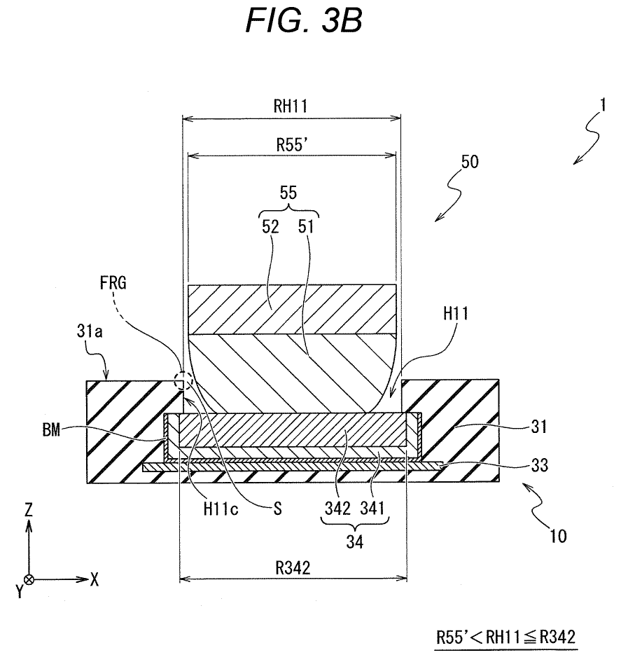

FIG. 3A is a cross-sectional view illustrating a configuration example of the pad electrode 34 of the sensor element 10, the bump electrode 55 of the logic chip 50 immediately before being bonded to the pad electrode 34 (that is, in an initial state), and a peripheral portion thereof, which are a part of the imaging device 1 according to the first embodiment of the present disclosure. FIG. 3B is a cross-sectional view illustrating a configuration example of the pad electrode 34 of the sensor element 10, the bump electrode 55 of the logic chip 50 after being bonded to the pad electrode 34, and the peripheral portion thereof, which are a part of the imaging device 1 according to the first embodiment of the present disclosure.

As illustrated in FIGS. 3A and 3B, the bump electrode 55 is separated from a peripheral edge portion FRG of an opening end of the pad opening H11 not only in the initial state before being bonded to the pad electrode 34 but also after being bonded. The bump electrode 55 and the peripheral edge portion FRG of the opening end of the pad opening H11 have a non-contact structure.

For example, as illustrated in FIG. 3A, the diameter of the bump electrode 55 in the initial state is denoted by R55. As illustrated in FIG. 3B, the diameter of the bump electrode 55 after being bonded is denoted by R55′. The diameters R55 and R55′ of the bump electrode 55 are both smaller than a diameter RH11 of the opening end of the pad opening H11. As a result, when a tip of the bump electrode 55 is brought into contact with a preset position of the pad electrode 34 (for example, a central portion of the pad electrode 34 in plan view), the bump electrode 55 does not come into contact with the peripheral edge portion FRG of the opening end of the pad opening H11 and with a side surface H11c of the pad opening H11.

In addition, in this state, reflow is performed to bond the bump electrode 55 to the pad electrode 34. Even after bonding, the bump electrode 55 is separated from the peripheral edge portion FRG and the side surface H11c and does not come into contact with them. The bump electrode 55 and the peripheral edge portion FRG, and the bump electrode 55 and the side surface H11c are separated from each other not only at the initial stage of the bonding process but also after bonding, and a space S is secured.

Note that the reflow is a process of arranging a substrate including the sensor element 10 and the logic chip 50 in a heat treatment device called a reflow furnace in a state where the tip of the bump electrode 55 of the logic chip 50 is brought into contact with the pad electrode 34 of the sensor element 10, melting at least a part of the bump electrode 55 (for example, an alloy layer 51 described later) in the reflow furnace, and bonding the bump electrode 55 to the pad electrode 34.

The pad electrode 34 includes, for example, an electrode film and a barrier metal BM provided between the electrode film and the wiring 33. The electrode film includes, for example, a cobalt (Co) film 341 and a copper (Cu) film 342 provided on the Co film 341. The bump electrode 55 is bonded to the Cu film 342, and is electrically connected to the wiring 33 via the pad electrode 34 including the Cu film 342 and the like.

The bump electrode 55 includes, for example, the alloy layer 51 constituted by an alloy of tin (Sn) and silver (Ag), and an Ni layer 52. The alloy layer 51 is bonded to the Cu film 342 of the pad electrode 34.

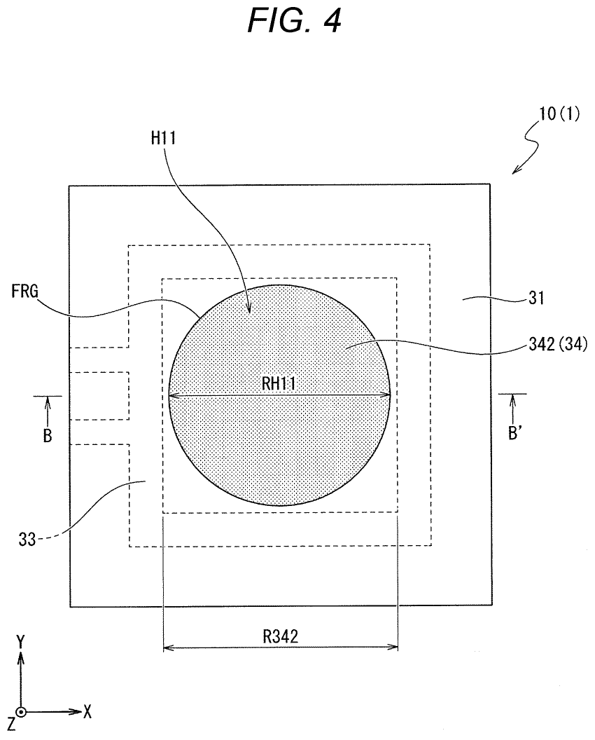

FIG. 4 is a plan view illustrating a configuration example (part 1) of the pad opening H11 of the sensor element 10 and a peripheral portion thereof according to the first embodiment of the present disclosure. As illustrated in FIG. 4, a shape of the pad opening H11 in plan view from the Z-axis direction (hereinafter, referred to as a planar shape) is, for example, a perfect circle. In this case, the diameter of this perfect circle corresponds to the diameter RH11 described above.

In the first configuration example, the diameter RH11 of the pad opening H11 is equal to a diameter R342 of the Cu film 342 of the pad electrode 34 or smaller than the diameter R34. The planar shape of the Cu film 342 is, for example, a square. The length of one side of this square corresponds to the diameter R342 of the Cu film 342.

A perfect-circle bottom surface of the pad opening H11 is the Cu film 342 of the pad electrode 34, and the bump electrode 55 (see, for example, FIGS. 3A and 3B) is bonded to the Cu film 342 on the bottom surface. Note that a cross section taken along line B-B′ in FIG. 4 corresponds to a cross section of the pad opening H11 and the peripheral portion thereof illustrated in FIGS. 3A and 3B.

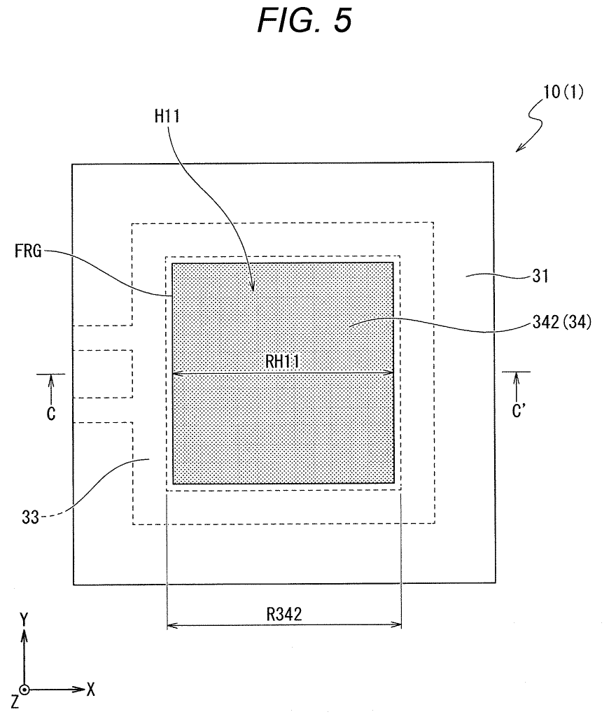

In the embodiment of the present disclosure, the planar shape of the pad opening H11 is not limited to a perfect circle. FIG. 5 is a plan view illustrating a configuration example (part 2) of the pad opening H11 of the sensor element 10 and the peripheral portion thereof according to the first embodiment of the present disclosure. As illustrated in FIG. 5, the planar shape of the pad opening H11 may be a square. In this case, the length of one side of the square corresponds to the diameter RH11 described above.

Also in the second configuration example, similarly to the first configuration example illustrated in FIG. 4, the diameter RH11 of the pad opening H11 is smaller than the diameter R342 of the Cu film 342 of the pad electrode 34.

A square bottom surface of the pad opening H11 is the Cu film 342 of the pad electrode 34, and the bump electrode 55 (see, for example, FIGS. 3A and 3B) is bonded to the Cu film 342 on the bottom surface. Note that a cross section taken along line C-C′ in FIG. 5 corresponds to the cross section of the pad opening H11 and the peripheral portion thereof illustrated in FIGS. 3A and 3B.

### Effects of First Embodiment

As described above, the imaging device 1 according to the first embodiment of the present disclosure includes the sensor element 10 including the pixel region 100A and the peripheral region 100B located around the pixel region 100A, and the logic chip 50 including the bump electrode 55. The sensor element 10 includes the silicon substrate 11, the photoelectric conversion section 12 provided in the silicon substrate 11 in the pixel region 100A, the pad electrode 34 provided on the back surface 11S1 side of the silicon substrate 11 in the peripheral region 100B, and the interlayer insulating film 31 provided on the back surface 11S1 side of the silicon substrate 11. The interlayer insulating film 31 is provided with the pad opening H11 that opens a portion above the pad electrode 34. The bump electrode 55 is bonded to the pad electrode 34 in a state of being separated from the peripheral edge portion FRG of the opening end of the pad opening H11.

With this configuration, for example, at the initial stage of the bonding process of arranging the bump electrode 55 before melting (see, for example, FIG. 3A) on the pad electrode 34, the tip of the bump electrode 55 can be brought into contact with the front surface of the pad electrode 34 without bringing the bump electrode 55 into contact with the peripheral edge portion FRG of the opening end of the pad opening H11. Even in a case where the height of the sensor element 10 increases and the depth of the pad opening H11 increases, it is easy to bring the tip of the bump electrode 55 into contact with the front surface of the pad electrode 34.

When the tip of the bump electrode 55 is brought into contact with the front surface of the pad electrode 34 and melt-bonded, the bump electrode 55 is separated from (that is, not in contact with) the peripheral edge portion FRG of the opening end of the pad opening H11. Since the bump electrode 55 in the molten state is cooled and solidified while maintaining the non-contact state with the peripheral edge portion FRG, it is possible to prevent the bump electrode 55 from being formed in a distorted shape along the peripheral edge portion FRG. As a result, it is possible to suppress generation of stress (internal stress) inside the bump electrode 55, and it is possible to suppress generation of a crack in the bump electrode 55 due to the internal stress.

It becomes easy to expand the bump electrode 55 in the molten state in the horizontal direction parallel to the pad electrode 34 without bringing the bump electrode 55 into contact with the side surface H11c of the pad opening H11. As a result, the height of the bump electrode 55 can be reduced. By reducing the height of the bump electrode 55, the physical distance between the logic chip 50 and the pad electrode 34 can be reduced.

The bump electrode 55 in the molten state is separated from at least the peripheral edge portion FRG of the opening end of the pad opening H11. More preferably, the bump electrode 55 in the molten state is separated not only from the peripheral edge portion FRG but also from the side surface H11c of the pad opening H11. As a result, since the bump electrode 55 in the molten state has an increased contact interface with air as compared with a case where the bump electrode 55 comes into contact with the peripheral edge portion FRG and the side surface H11c, the surface tension can be increased. As a result, the height of the bump electrode 55 can be further reduced, and the physical distance between the logic chip 50 and the pad electrode 34 can be further reduced.

The surface tension will be described in more detail. When the bump electrode 55 in the molten state comes into contact with the pad electrode 34, the surface tension acts, and an alloy layer (not illustrated) is formed on the bump electrode 55 and the pad electrode 34 in a state where contraction/repulsion forces are balanced. Since the bump electrode 55 and the peripheral edge portion FRG are not in contact with each other, the formation of the alloy layer (not illustrated) proceeds in the horizontal direction, and the distance between the logic chip 50 and the pad electrode 34 is reduced. In such a state in which the distance is reduced, the surface tension acts in a direction in which the bump electrode 55 is crushed, and the bondability between the bump electrode 55 and the pad electrode 34 is improved.

As a phenomenon of the entire logic chip 50, when the distance between the logic chip 50 and the pad electrode 34 is reduced, the total contact area between the bump electrode 55 and the pad electrode 34 increases and the surface tension acts for each bump electrode 55, and thus it becomes easy to bond the logic chip 50 to the sensor element 10.

For example, even in a case where deformation or distortion occurs in the logic chip 50 when the bump electrode 55 is melt-bonded to the pad electrode 34, the surface tension acts for each bump electrode 55 as a phenomenon of the entire logic chip 50, and the bondability is improved for each bump electrode 55.

As a result, even in a case where deformation or distortion occurs in the logic chip 50, followability to the deformation or distortion is improved, and thus it becomes easy to bond the logic chip 50 to the sensor element 10.

From the above, it is possible to improve the bondability between the bump electrode 55 and the pad electrode 34.

### Modifications of First Embodiment

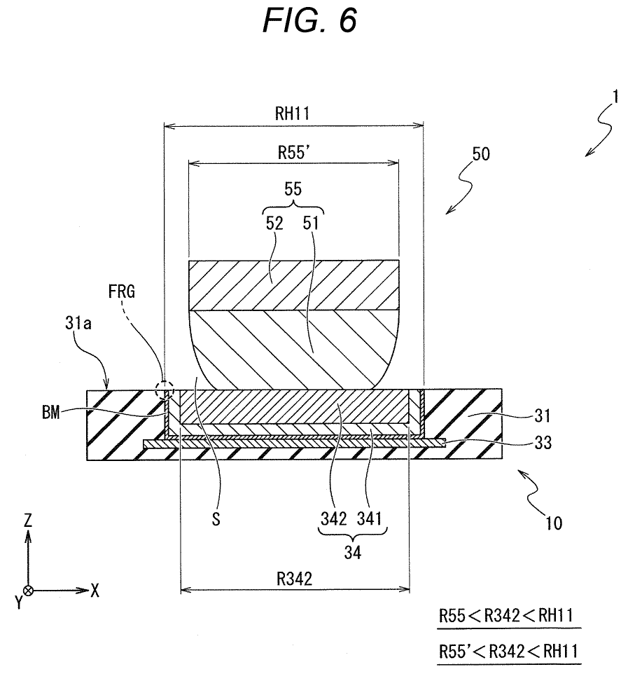

(1) First modification FIG. 6 is a cross-sectional view illustrating a first modification of the imaging device 1 according to the first embodiment of the present disclosure. As illustrated in FIG. 6, in the imaging device 1, the height of the pad opening H11 (see, for example, FIGS. 3A and 3B) is zero (0), and the front surface of the pad electrode 34 may be flush with a front surface 31a of the interlayer insulating film 31. In the first modification, a portion right above the pad electrode 34 including the barrier metal BM, the Co film 341, and the Cu film 342 corresponds to the pad opening H11.

In the first modification, the diameter R342 of the Cu film 342 of the pad electrode 34 is larger than the diameter R55 of the bump electrode 55 in the initial state (or the diameter R55′ of the bump electrode after bonding). In addition, the diameter RH11 of the pad opening H11 (that is, right above the pad electrode 34) is larger than the diameter R342 of the Cu film 342.

Even in such an aspect, it is possible to prevent the bump electrode 55 from being formed in a distorted shape along the peripheral edge portion FRG. As a result, it is possible to suppress generation of internal stress in the bump electrode 55, and it is possible to suppress generation of a crack in the bump electrode 55 due to the internal stress.

It is possible to expand the bump electrode 55 in the molten state in the horizontal direction parallel to the pad electrode 34 without bringing the bump electrode 55 into contact with the side surface H11c of the pad opening H11. As a result, the height of the bump electrode 55 can be reduced. By reducing the height of the bump electrode 55, the physical distance between the logic chip 50 and the pad electrode 34 can be reduced.

Similarly to the first embodiment described above, also in the first modification, it is possible to improve the bondability between the bump electrode 55 and the pad electrode 34.

### (2) Second Modification

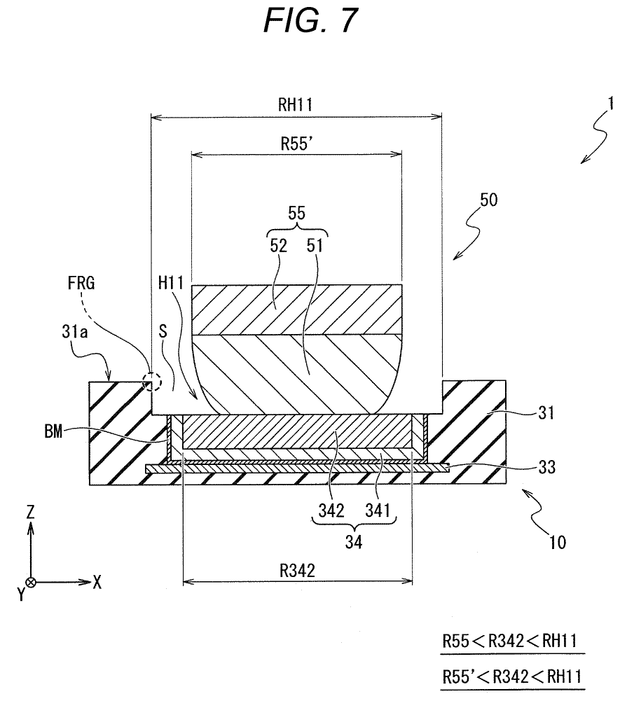

FIG. 7 is a cross-sectional view illustrating a second modification of the imaging device 1 according to the first embodiment of the present disclosure. As illustrated in FIG. 7, in the second modification the imaging device 1, the height of the pad opening H11 is larger than zero (0). The pad opening H11 of the second modification has a depth similar to the configuration example of the first embodiment illustrated in FIGS. 3A and 3B.

Similarly to the first modification described above, in the second modification, the diameter R342 of the Cu film 342 of the pad electrode 34 is larger than the diameter R55 of the bump electrode 55 in the initial state (or the diameter R55′ of the bump electrode after bonding). In addition, the diameter RH11 of the pad opening H11 (that is, right above the pad electrode 34) is larger than the diameter R342 of the Cu film 342. As a result, a part of the bottom surface of the pad opening H11 is constituted by the interlayer insulating film 31. The peripheral edge portion FRG of the opening end of the pad opening H11 is located outside an end portion of the Cu film 342 (that is, a side farther from the central portion of the Cu film 342) in the horizontal direction parallel to the X-axis direction and the Y-axis direction.

According to such an aspect, as compared with the first embodiment described above, the space S between the side surface H11c of the pad opening H11 and the bump electrode 55 can be further expanded. As a result, it becomes easier to expand the bump electrode 55 in the molten state in the horizontal direction parallel to the pad electrode 34 without bringing the bump electrode 55 into contact with the side surface H11c of the pad opening H11.

Similarly to the first embodiment described above, also in the second modification, it is possible to improve the bondability between the bump electrode 55 and the pad electrode 34.

### Second Embodiment

In an embodiment of the present disclosure, each of a plurality of pad openings H11 may be constituted by a plurality of openings.

### Configuration Example

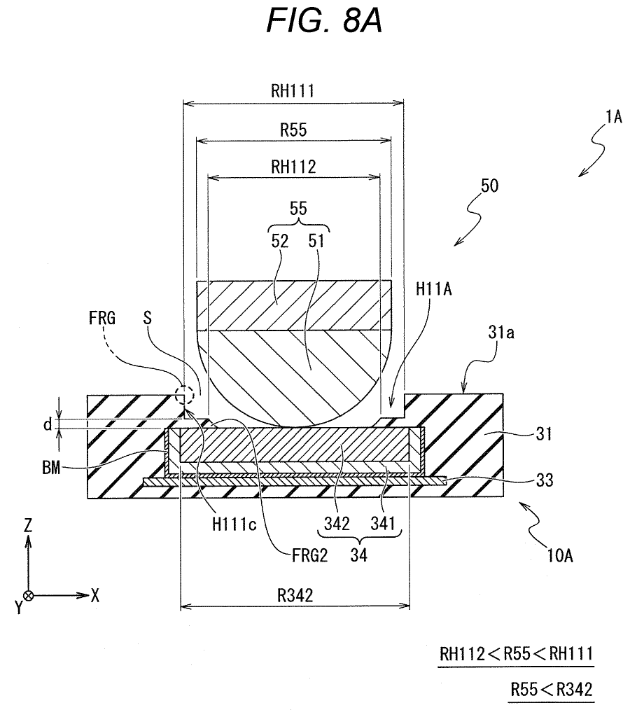

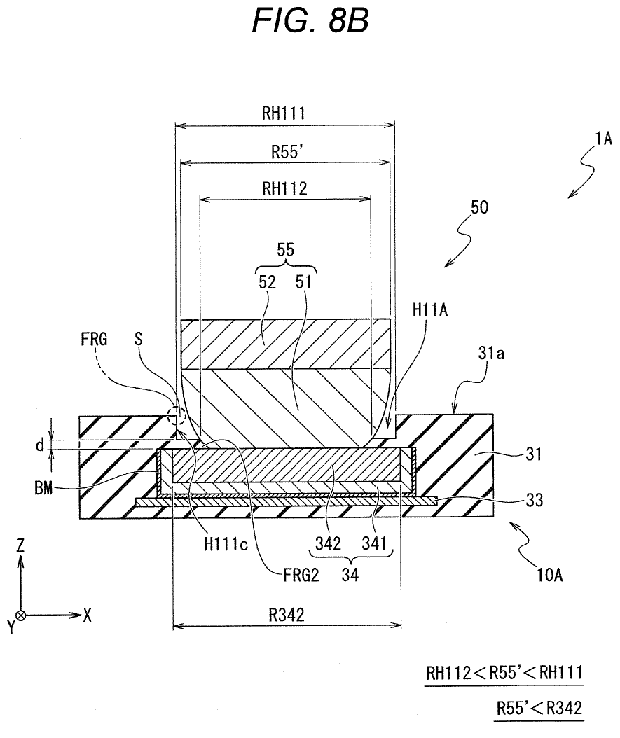

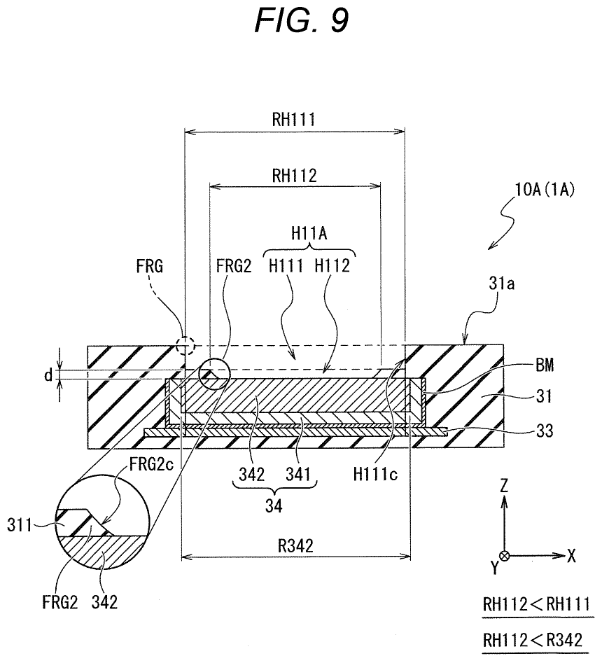

FIG. 8A is a cross-sectional view illustrating a configuration example of a pad electrode 34 of a sensor element 10, a bump electrode 55 of a logic chip 50 immediately before being bonded to the pad electrode 34 (that is, in an initial state), and a peripheral portion thereof, which are a part of an imaging device 1A according to a second embodiment of the present disclosure. FIG. 8B is a cross-sectional view illustrating a configuration example of the pad electrode 34 of the sensor element 10, the bump electrode 55 of the logic chip 50 after being bonded to the pad electrode 34, and the peripheral portion thereof, which are a part of the imaging device 1A according to the second embodiment of the present disclosure. FIG. 9 is a cross-sectional view illustrating a configuration example of a pad opening H11A according to the second embodiment of the present disclosure.

As illustrated in FIGS. 8A to 9, the pad opening H11A according to the second embodiment includes a first opening H111 including a peripheral edge portion FRG of an opening end (an upper end in the drawing), and a second opening H112 communicating with the first opening H111 and having a Cu film 342 of the pad electrode 34 as a bottom surface. The diameter of the second opening H112 is smaller than that of the first opening H111. Denoting the diameter of the first opening H111 as RH111 and the diameter of the second opening H112 as RH112, the diameter RH112 is smaller than the diameter RH111.

When the peripheral edge portion FRG of the opening end of the pad opening H11A is defined as an outer peripheral edge portion, the pad opening H11A includes an inner peripheral edge portion FRG2 provided at a peripheral edge of the second opening H112. The inner peripheral edge portion FRG2 is provided between a bottom surface of the first opening H111 and the front surface of the pad electrode 34 (that is, the Cu film 342), and is provided in at least a part of the second opening H112. In the second embodiment, as illustrated in FIG. 10 described later, the inner peripheral edge portion FRG2 is provided at the entire peripheral edge of the second opening H112 in plan view from the Z-axis direction.

FIG. 10 is a plan view illustrating a configuration example of the pad opening H11A of the sensor element 10A and the peripheral portion thereof according to the second embodiment of the present disclosure. FIG. 10 illustrates a case where the first opening H111 and the second opening H112 have planar shapes different from each other. As illustrated in FIG. 10, the planar shape of the first opening H111 of the pad opening H11A is, for example, a square. In this case, the diameter of this perfect circle corresponds to the diameter RH111. In addition, the planar shape of the second opening H112 of the pad opening H11A is, for example, a perfect circle. In this case, the diameter of this perfect circle corresponds to the diameter RH112.

The perfect-circle bottom surface of the second opening H112 is the Cu film 342 of the pad electrode 34, and the bump electrode 55 (see, for example, FIGS. 8A and 8B) is bonded to the Cu film 342 on the bottom surface.

In a bottom portion of the first opening H111, a region where the second opening H112 is not provided is constituted by an interlayer insulating film 31. Since this region is recessed from a front surface 31a of the interlayer insulating film 31, it may be referred to as a recessed portion 311. An end portion of the recessed portion 311 on the second opening H112 side is the inner peripheral edge portion FRG2. In the second embodiment, the recessed portion 311 including the inner peripheral edge portion FRG2 is provided at the entire peripheral edge of the second opening H111. Note that a cross section taken along line D-D′ in FIG. 10 corresponds to a cross section of the pad opening H11A and the peripheral portion thereof illustrated in FIGS. 8A, 8B, and 9.

As illustrated in FIG. 8A, both of a diameter R55 of the bump electrode 55 immediately before bonding (that is, in the initial state) and a diameter R55′ of the bump electrode 55 after bonding are smaller than the diameter RH111 of the opening end of the first opening H111. As a result, when a tip of the bump electrode 55 is brought into contact with a preset position of the pad electrode 34 (for example, a central portion of the pad electrode 34 in plan view), the bump electrode 55 does not come into contact with the outer peripheral edge portion FRG of the opening end of the first opening H111 and with a side surface H111c of the first opening H111.

In this state, reflow is performed to bond the bump electrode 55 to the pad electrode 34. Even after bonding, the bump electrode 55 is separated from the outer peripheral edge portion FRG and the side surface H111c and does not come into contact with them. The bump electrode 55 and the outer peripheral edge portion FRG, and the bump electrode 55 and the side surface H111c are separated from each other not only at the initial stage of the bonding process but also after bonding, and a space S is secured.

### Effects of Second Embodiment

In the imaging device 1A according to the second embodiment, the bump electrode 55 is bonded to the pad electrode 34 in a state of being separated from at least the outer peripheral edge portion FRG of the pad opening H11. As a result, the imaging device 1A achieves effects similar to those of the imaging device 1 according to the first embodiment.

That is, at the initial stage of the bonding process of arranging the bump electrode 55 before melting (see, for example, FIG. 8A) on the pad electrode 34, a tip of the bump electrode 55 can be brought into contact with the front surface of the pad electrode 34 without bringing the bump electrode 55 into contact with the outer peripheral edge portion FRG of the pad opening H11A. Even in a case where the height of the sensor element 10A increases and the depth of the pad opening H11A increases, it is easy to bring the tip of the bump electrode 55 into contact with the front surface of the pad electrode 34.

When the tip of the bump electrode 55 is brought into contact with the front surface of the pad electrode 34 and melt-bonded, the bump electrode 55 is separated from (that is, not in contact with) the outer peripheral edge portion FRG of the pad opening H11A. Since the bump electrode 55 in the molten state is cooled and solidified while maintaining the non-contact state with the outer peripheral edge portion FRG, it is possible to prevent the bump electrode 55 from being formed in a distorted shape along the outer peripheral edge portion FRG. As a result, it is possible to suppress generation of stress (internal stress) inside the bump electrode 55, and it is possible to suppress generation of a crack in the bump electrode 55 due to the internal stress.

It becomes easy to expand the bump electrode 55 in the molten state in the horizontal direction parallel to the pad electrode 34 without bringing the bump electrode 55 into contact with the side surface H111c of the first opening H111. As a result, the height of the bump electrode 55 can be reduced. By reducing the height of the bump electrode 55, the physical distance between the logic chip 50 and the pad electrode 34 can be reduced.

The bump electrode 55 in the molten state is separated from at least the outer peripheral edge portion FRG of the pad opening H11. More preferably, the bump electrode 55 in the molten state is separated not only from the outer peripheral edge portion FRG but also from the side surface H111c of the first opening H111. As a result, since the bump electrode 55 in the molten state has an increased contact interface with air as compared with a case where the bump electrode 55 comes into contact with the outer peripheral edge portion FRG and the side surface H111c, the surface tension can be increased. As a result, the height of the bump electrode 55 can be further reduced, and the physical distance between the logic chip 50 and the pad electrode 34 can be further reduced.

The detailed description of the surface tension is similar to that in the first embodiment. Since the bump electrode 55 and the outer peripheral edge portion FRG are not in contact with each other, the formation of the alloy layer (not illustrated) proceeds in the horizontal direction, and the distance between the logic chip 50 and the pad electrode 34 is reduced. In such a state in which the distance is reduced, the surface tension acts in a direction in which the bump electrode 55 is crushed, and the bondability between the bump electrode 55 and the pad electrode 34 is improved. As a phenomenon of the entire logic chip 50, when the distance between the logic chip 50 and the pad electrode 34 is reduced, the total contact area between the bump electrode 55 and the pad electrode 34 increases and the surface tension acts for each bump electrode 55, and thus it becomes easy to bond the logic chip 50 to the sensor element 10A.

Similarly to the first embodiment, even in a case where deformation or distortion occurs in the logic chip 50, followability to the deformation or distortion is improved, and thus it becomes easy to bond the logic chip 50 to the sensor element 10A.

From the above, it is possible to improve the bondability between the bump electrode 55 and the pad electrode 34.

In addition, in the imaging device 1A, an opening surface (that is, a bonding surface with the bump electrode 55) of the pad electrode 34 is defined by the second opening H112. The size (for example, diameter) , planar shape, and arrangement interval of the first openings H111 are restricted by the bump electrode 55, but the size, planar shape, and arrangement interval of the second openings H112 are less restricted by the bump electrode 55, and can be set relatively freely. As a result, the degree of freedom in designing the pad electrode 34 and the bump electrode 55 can be increased.

For example, the size, planar shape, and arrangement interval of the second openings H112 can be changed without changing the size, planar shape, and arrangement position of the first openings H111 and the bump electrode 55. As a result, the size, planar shape, and arrangement interval of the pad electrodes 34 can also be changed. For example, by changing the size, planar shape, and arrangement interval of the second openings H112, it becomes easy to shrink the arrangement interval of the pad electrodes 34 and the wirings.

By changing the arrangement interval of the second openings H112, it may be possible to shrink the arrangement interval of the bump electrodes 55 bonded to the pad electrodes 34 through the second openings H112. As a result, it may be possible to contribute to reduction in the chip size of the logic chip 50.

As described above, the imaging device 1A according to the second embodiment has many advantages such that, for example, the bondability between the bump electrode 55 and the pad electrode 34 can be improved similarly to the imaging device 1, and further, the degree of freedom in designing the pad electrode 34 and the bump electrode 55 can be increased.

Note that a thickness d of the inner peripheral edge portion FRG2 is preferably 1 μm or less. As a result, in the bump electrode 55, the internal stress generated by the contact with the inner peripheral edge portion FRG2 can be suppressed as small as possible. This similarly applies to the modifications of the second embodiment and the third embodiment described later.

As illustrated in FIG. 9, an inner side surface FRG-2 of the inner peripheral edge portion FRG2 may be inclined or curved with respect to the bottom surface of the second opening H112 such that the diameter of the second opening H112 decreases as approaching the bottom surface of the second opening H112 (that is, the Cu film 342) from the opening end of the second opening H112. FIG. 9 illustrates a case where the side surface FRG-2 is curved. As a result, the inner side surface FRG-2 of the inner peripheral edge portion FRG2 can follow the shape of the bump electrode 55 in the initial state, and there is a possibility that the internal stress generated by the contact with the inner peripheral edge portion FRG2 can be further reduced.

### Modifications of Second Embodiment

### (1) First to Fourth Modifications

In the second embodiment described above, it has been described that the planar shape of the first opening H111 which is a part of the pad opening H11A is a square, and the planar shape of the second opening H112 which is another part of the pad opening H11A is a perfect circle. However, in the second embodiment of the present disclosure, the planar shapes of the first opening H111 and the second opening H112 are not limited thereto.

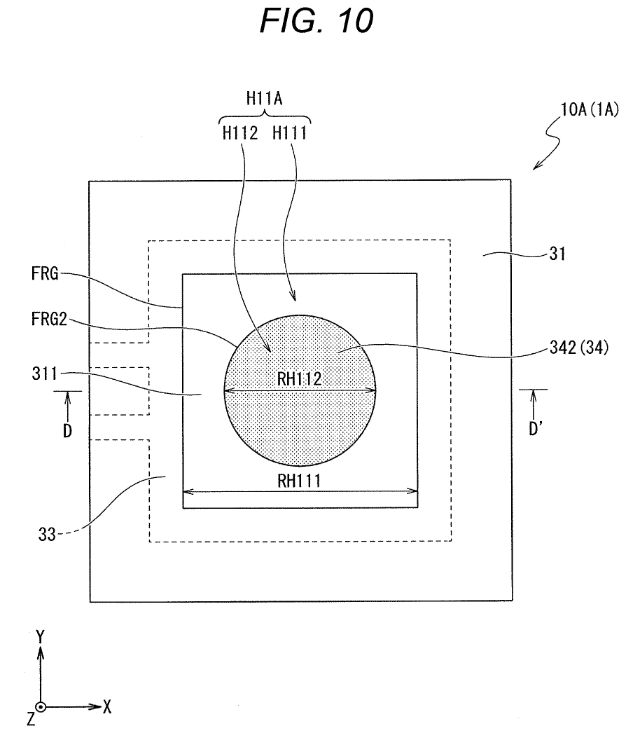

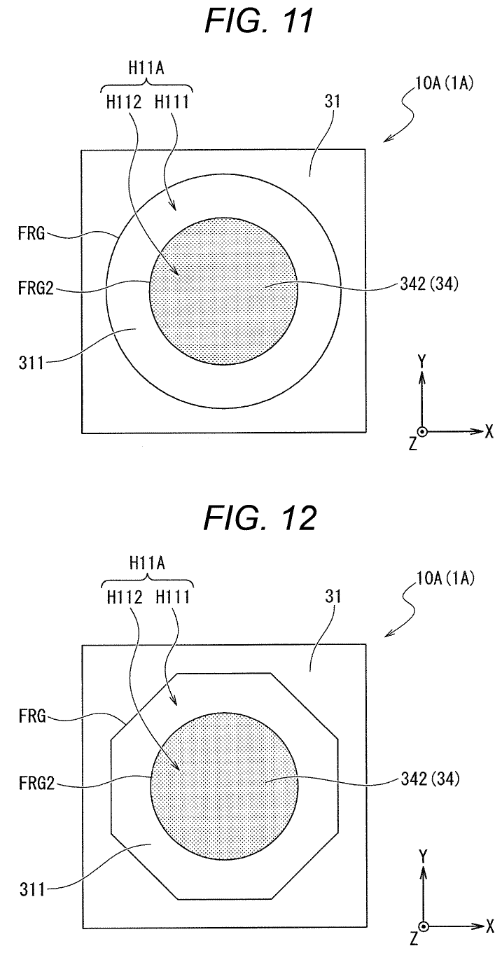

FIGS. 11 to 14 are plan views illustrating first to fourth modifications of the imaging device 1A according to the second embodiment of the present disclosure. FIGS. 11, 13, and 14 illustrate cases where the first opening H111 and the second opening H112 have the same planar shape. FIG. 12 illustrates a case where the first opening H111 and the second opening H112 have planar shapes different from each other.

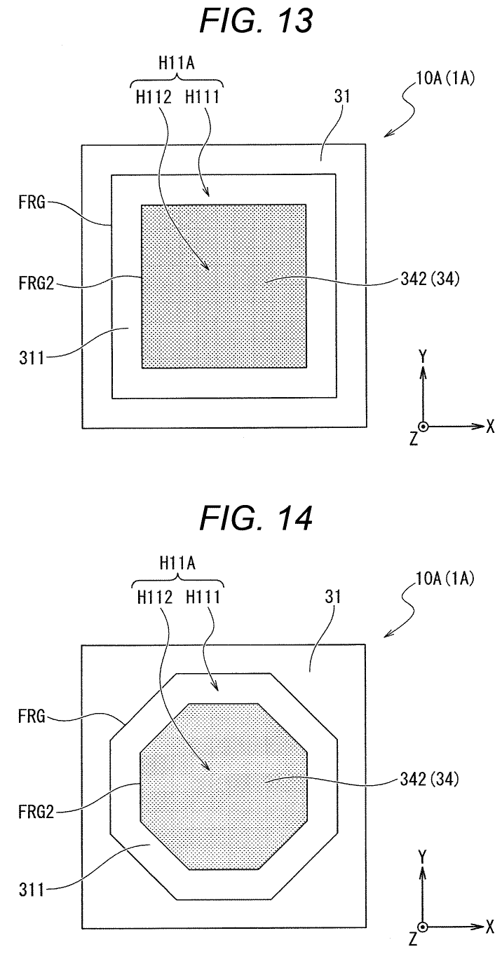

As illustrated in FIG. 11, each planar shape of the first opening H111 and the second opening H112 may be a perfect circle. As illustrated in FIG. 12, the planar shape of the first opening H111 may be a regular octagon, and the planar shape of the second opening H112 may be a perfect circle. As illustrated in FIG. 13, each planar shape of the first opening H111 and the second opening H112 may be a square. As illustrated in FIG. 14, each planar shape of the first opening H111 and the second opening H112 may be a regular octagon.

In any of the cases of first to fourth modifications illustrated in FIGS. 11 to 14, similarly to the second embodiment, the bump electrode 55 and the outer peripheral edge portion FRG are not in contact with each other not only at the initial stage of the bonding process but also after bonding. The space S is secured between the bump electrode 55 and the outer peripheral edge portion FRG. As a result, effects similar to those of the second embodiment described above are achieved.

### (2) Fifth Modification

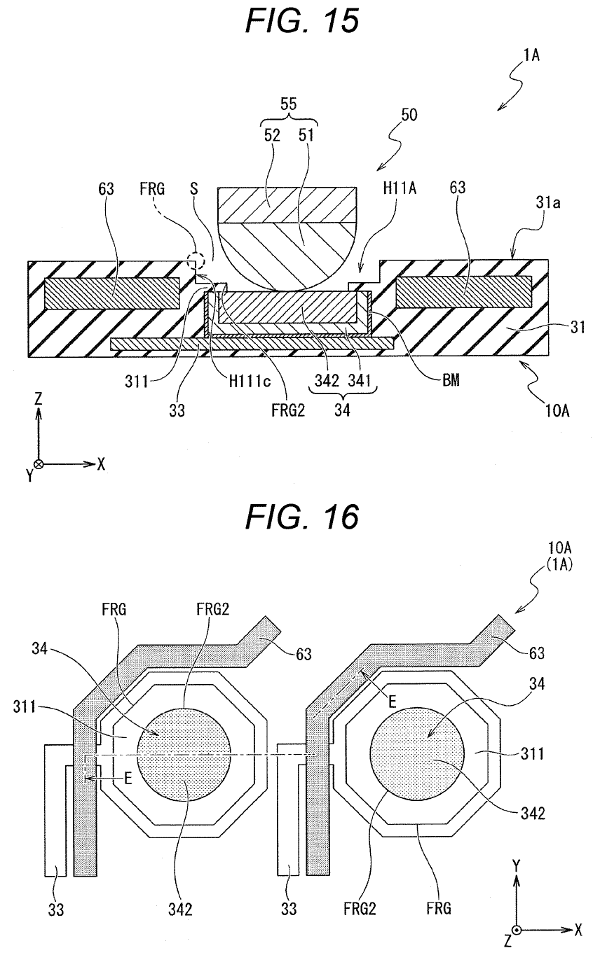

FIG. 15 is a cross-sectional view illustrating a fifth modification of the imaging device 1A according to the second embodiment of the present disclosure. FIG. 16 is a plan view illustrating the fifth modification of the imaging device 1A according to the second embodiment of the present disclosure. A cross section taken along line E-E′ in FIG. 16 corresponds to a cross section illustrated in FIG. 15.

As illustrated in FIGS. 15 and 16, the imaging device 1A may include a wiring 63 provided around the pad opening H11A. The wiring 63 is connected to another pad electrode (not illustrated) constituted by aluminum (Al) or the like, for example.

A part of the interlayer insulating film 31 is interposed between the wiring 63 and the pad electrode 34 and between the wiring 63 and the wiring 33. As a result, the wiring 63 is insulated from the pad electrode 34 and the wiring 33.

The wiring 63 is covered with another part of the interlayer insulating film 31 and is separated from the pad opening H11A. As a result, the wiring 63 is insulated from the bump electrode 55.

Even in such an aspect, the bump electrode 55 and the outer peripheral edge portion FRG are not in contact with each other not only at the initial stage of the bonding process but also after bonding. The space S is secured between the bump electrode 55 and the outer peripheral edge portion FRG. As a result, effects similar to those of the second embodiment described above are achieved.

### (3) Sixth Modification

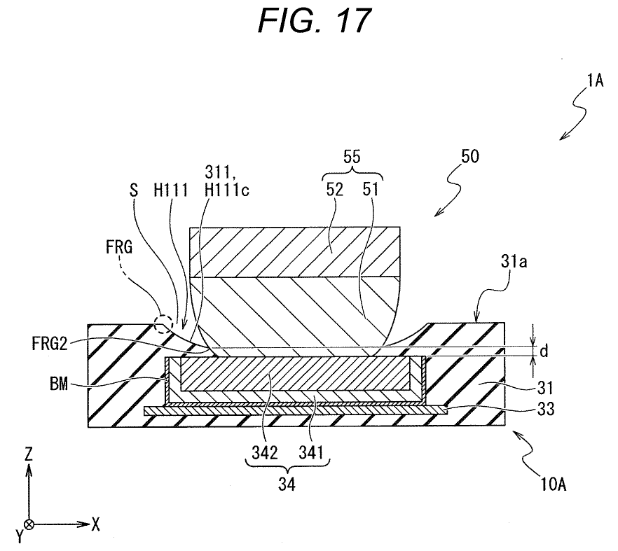

FIG. 17 is a cross-sectional view illustrating a sixth modification of the imaging device 1A according to the second embodiment of the present disclosure. As illustrated in FIG. 17, the side surface H111c of the first opening H111 may be inclined or curved with respect to the bottom surface of the first opening H111 such that the diameter of the first opening H111 decreases as approaching the bottom surface of the first opening H111 (that is, the recessed portion 311) from the opening end of the first opening H111. In the sixth modification, since the side surface H111c of the first opening H111 is curved, it is also the curved recessed portion 311. For this reason, it may be said that the recessed portion 311 is inclined so as to be deeper from the front surface 31a as approaching the inner peripheral edge portion FRG2 from the outer peripheral edge portion FRG.

Even in such an aspect, the bump electrode 55 and the outer peripheral edge portion FRG are not in contact with each other not only at the initial stage of the bonding process but also after bonding. The space S is secured between the bump electrode 55 and the outer peripheral edge portion FRG. As a result, effects similar to those of the second embodiment described above are achieved.

### (4) Seventh and Eighth Modifications

In the second embodiment of the present disclosure, the recessed portion 311 may have an uneven portion.

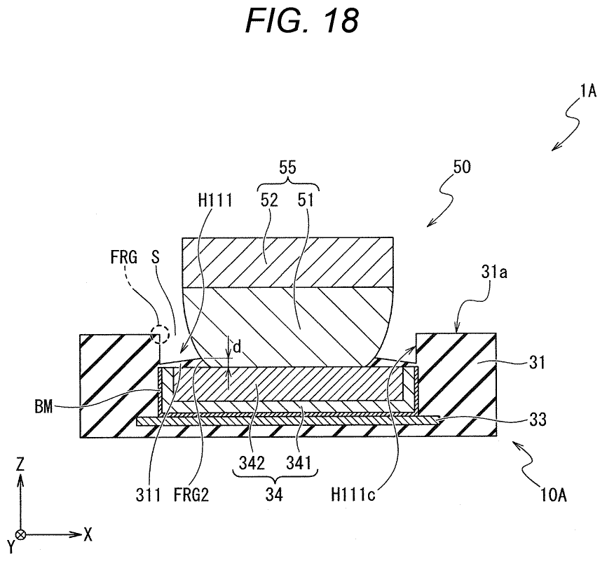

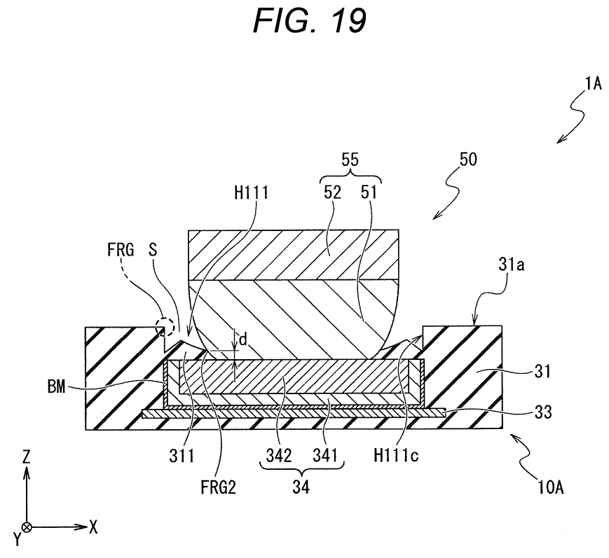

FIG. 18 is a cross-sectional view illustrating a seventh modification of the imaging device 1A according to the second embodiment of the present disclosure. FIG. 19 is a cross-sectional view illustrating an eighth modification of the imaging device 1A according to the second embodiment of the present disclosure. As illustrated in FIG. 18, the vertex of the uneven portion in the recessed portion 311 may be located at the middle between the outer peripheral edge portion FRG and the inner peripheral edge portion FRG2. As illustrated in FIG. 19, the vertex of the uneven portion in the recessed portion 311 may be located at the inner peripheral edge portion FRG2.

In any aspect of the seventh modification illustrated in FIG. 18 and the eighth modification illustrated in FIG. 19, the bump electrode 55 and the outer peripheral edge portion FRG are not in contact with each other not only at the initial stage of the bonding process but also after bonding. The space S is secured between the bump electrode 55 and the outer peripheral edge portion FRG. As a result, effects similar to those of the second embodiment described above are achieved.

### Third Embodiment

In the second embodiment described above, the aspect in which the recessed portion 311 is provided at the entire peripheral edge of the second opening H112 in plan view from the Z-axis direction has been described. However, the embodiment of the present disclosure is not limited thereto. A recessed portion 311 may be provided only on a part of a peripheral edge of a second opening H112.

### Configuration Example

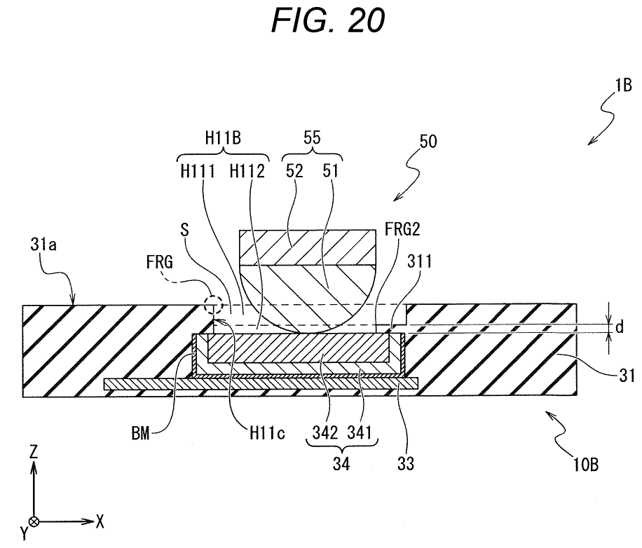

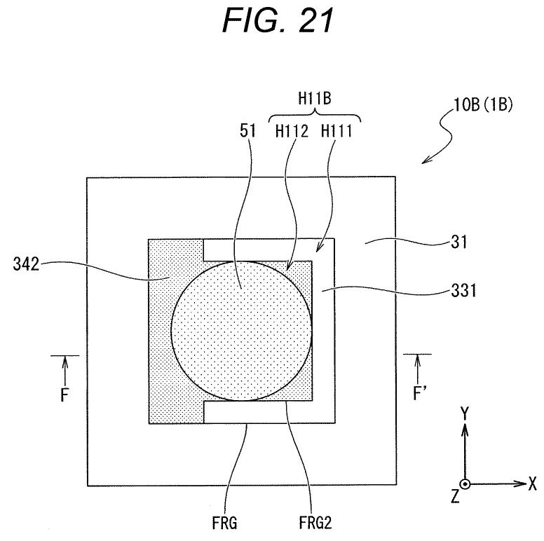

FIG. 20 is a cross-sectional view illustrating a configuration example of a pad electrode 34 of a sensor element 10B, a bump electrode 55 of a logic chip 50 immediately before being bonded to the pad electrode 34 (that is, in an initial state), and a peripheral portion thereof, which are a part of an imaging device 1B according to a third embodiment of the present disclosure. FIG. 21 is a plan view illustrating a configuration example of a pad opening H11A of the sensor element 10B and a peripheral portion thereof, which are a part of the imaging device 1B according to the third embodiment of the present disclosure. Note that a cross section taken along line F-F′ in FIG. 21 corresponds to a cross section of the pad opening H11B and the peripheral portion thereof illustrated in FIG. 20.

As illustrated in FIGS. 20 and 21, the pad opening H11B according to the third embodiment includes a first opening H111 including a peripheral edge portion FRG of an opening end (an upper end in the drawing), and the second opening H112 communicating with the first opening H111 and having a Cu film 342 of the pad electrode 34 as a bottom surface. In the third embodiment, similarly to the second embodiment, the diameter of the second opening H112 is smaller than that of the first opening H111. In addition, the recessed portion 311 of the sensor element 10B is provided only on a part of the peripheral edge of the second opening H112.

### Effects of Third Embodiment

Even in the aspects illustrated in FIGS. 20 and 21, the bump electrode 55 and the outer peripheral edge portion FRG are not in contact with each other not only at the initial stage of a bonding process but also after bonding. A space S is secured between the bump electrode 55 and the outer peripheral edge portion FRG. As a result, effects similar to those of the second embodiment are achieved.

### Modifications of Third Embodiment

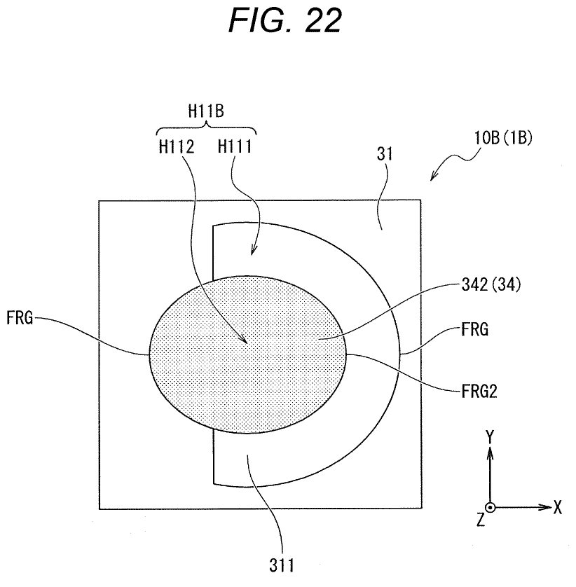

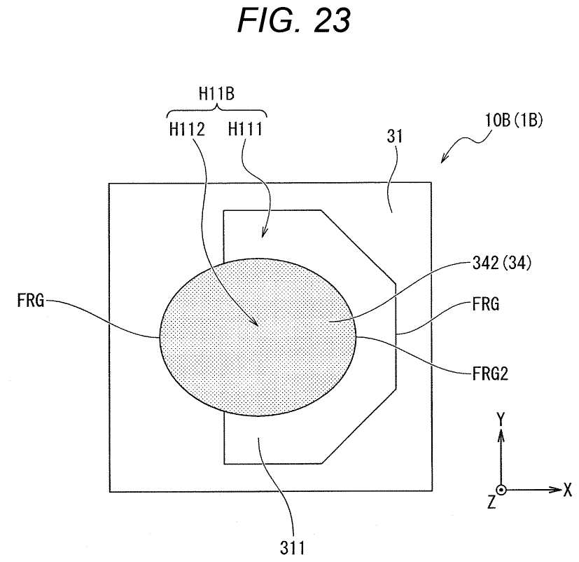

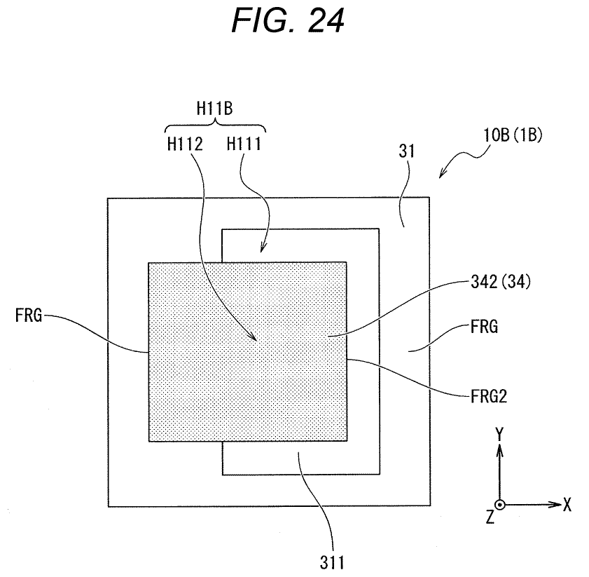

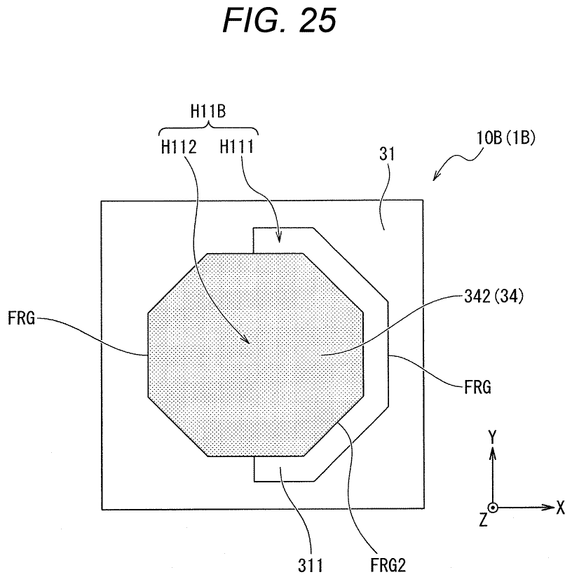

FIGS. 22 to 25 are plan views illustrating first to fourth modifications of the imaging device 1B according to the third embodiment of the present disclosure. FIG. 22 illustrates the first modification which is a case where the planar shape of the second opening H112 is an ellipse, and the planar shape of the first opening H111 is a shape obtained by combining an ellipse and a semi-ellipse having a diameter larger than that of the ellipse. FIG. 23 illustrates the second modification which is a case where the planar shape of the second opening H112 is an ellipse, and the planar shape of the first opening H111 is a shape obtained by combining an ellipse and a polygon having a diameter in one direction (for example, in the Y-axis direction) larger than that of the ellipse. FIG. 24 illustrates the third modification which is a case where the planar shape of the second opening H112 is a square, and the planar shape of the first opening H111 is a shape obtained by combining a square and a rectangle having a diameter in one direction (for example, in the Y-axis direction) larger than that of the square. FIG. 25 illustrates the fourth modification which is a case where the planar shape of the second opening H112 is an octagon, and the planar shape of the first opening H111 is a shape obtained by combining an octagon and a polygon (for example, a shape obtained by dividing an octagon into halves in plan view) having a diameter in one direction (for example, in the Y-axis direction) larger than that of the octagon.

As described above, in the third embodiment, the planar shape of the second opening H112 may be an arbitrary shape such as a perfect circle, an ellipse, or a polygon. In addition, the planar shape of the first opening H111 is also arbitrary. The planar shape of the first opening H111 may be, for example, a shape obtained by combining the planar shape of the second opening H112 and an arbitrary shape such as a perfect circle, an ellipse, or a polygon.

Even in such a case, the bump electrode 55 and the outer peripheral edge portion FRG are not in contact with each other not only at the initial stage of the bonding process but also after bonding. The space S is secured between the bump electrode 55 and the outer peripheral edge portion FRG. As a result, effects similar to those of the second embodiment are achieved.

### Application Example

### First Application Example

FIG. 26 illustrates, for example, an overall configuration of the imaging device 1 described in the first embodiment. The imaging device 1 is a CMOS image sensor, and includes a pixel section la as an imaging area on the silicon substrate 11, and a peripheral circuit section 130 including, for example, a row scanning section 131, a horizontal selection section 133, a column scanning section 134, and a system control section 132 in a peripheral region of the pixel section la. Note that, although the imaging device 1 is described in a first application example, the present configuration is applied to any of the imaging devices 1A and 1B according to the second and third embodiments.

The pixel section la includes, for example, a plurality of unit pixels P (corresponding to the photoelectric conversion section 12) two-dimensionally arranged in a matrix. In each of the unit pixels P for example, a pixel drive line Lread (specifically, a row selection line and a reset control line) is wired for each pixel row, and a vertical signal line Lsig is wired for each pixel column. The pixel drive line Lread transmits a drive signal for reading a signal from a pixel. One end of the pixel drive line Lread is connected to an output terminal corresponding to each row of the row scanning section 131.

The row scanning section 131 is constituted by a shift register, an address decoder, and the like, and is a pixel drive section that drives each unit pixel P of the pixel section la, for example, in units of rows. A signal output from each unit pixel P of the pixel row selectively scanned by the row scanning section 131 is supplied to the horizontal selection section 133 through each vertical signal line Lsig. The horizontal selection section 133 is constituted by an amplifier, a horizontal selection switch, and the like provided for each vertical signal line Lsig.

The column scanning section 134 is constituted by a shift register, an address decoder, and the like, and scans and sequentially drives each horizontal selection switch of the horizontal selection section 133. By the selective scanning performed by the column scanning section 134, a signal of each pixel transmitted through each vertical signal line Lsig is sequentially output to the horizontal signal line 135 and transmitted to the outside of the silicon substrate 11 through the horizontal signal line 135.

A circuit portion including the row scanning section 131, the horizontal selection section 133, the column scanning section 134, and the horizontal signal line 135 may be formed directly on the silicon substrate 11, or may be disposed in an external control IC. In addition, the circuit portions may be formed on another substrate connected by a cable or the like.

The system control section 132 receives a clock provided from the outside of the silicon substrate 11, data instructing an operation mode, and the like, and outputs data such as internal information of the imaging device 1. The system control section 132 further includes a timing generator that generates various kinds of timing signals, and performs drive control of peripheral circuits such as the row scanning section 131, the horizontal selection section 133, and the column scanning section 134 on the basis of the various kinds of timing signals generated by the timing generator.

### Second Application Example

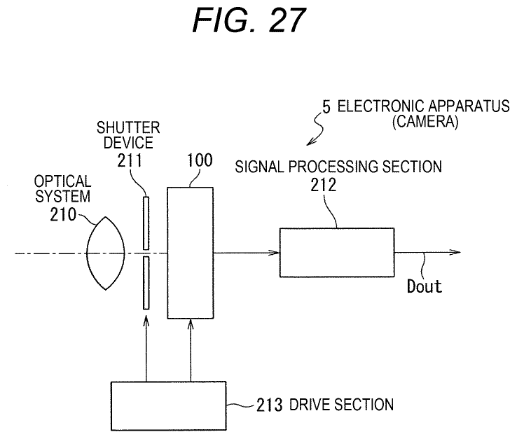

The above-described imaging device 1 can be applied to any type of imaging device having an imaging function, for example, a camera system such as a digital still camera or a video camera, a mobile phone having an imaging function, or the like. FIG. 27 illustrates a schematic configuration of an electronic apparatus 5 (camera) as an example. The electronic apparatus 5 is, for example, a video camera capable of capturing a still image or a moving image, and includes the imaging device 1, an optical system (optical lens) 210, a shutter device 211, a drive section 213 that drives the imaging device 1 and the shutter device 211, and a signal processing section 212.

The optical system 210 guides image light (incident light) from a subject to the pixel section la of the imaging device 1. The optical system 210 may include a plurality of optical lenses. The shutter device 211 controls a light irradiation period and a light shielding period for the imaging device 1. The drive section 213 controls a transfer operation of the imaging device 1 and a shutter operation of the shutter device 211. The signal processing section 212 performs various kinds of signal processing on a signal output from the imaging device 1. A video signal Dout after the signal processing is stored in a storage medium such as a memory or output to a monitor or the like.

Note that, although the imaging device 1 is described in a second application example, the present configuration is applied to any of the imaging devices 1A and 1B according to the second and third embodiments.

### Applied Example to Mobile Body

The technology according to the present disclosure (the present technology) can be applied to various products. For example, the technology according to the present disclosure may be implemented as a device mounted on any type of mobile body such as an automobile, an electric automobile, a hybrid electric automobile, a motorcycle, a bicycle, a personal mobility, an airplane, a drone, a ship, and a robot.

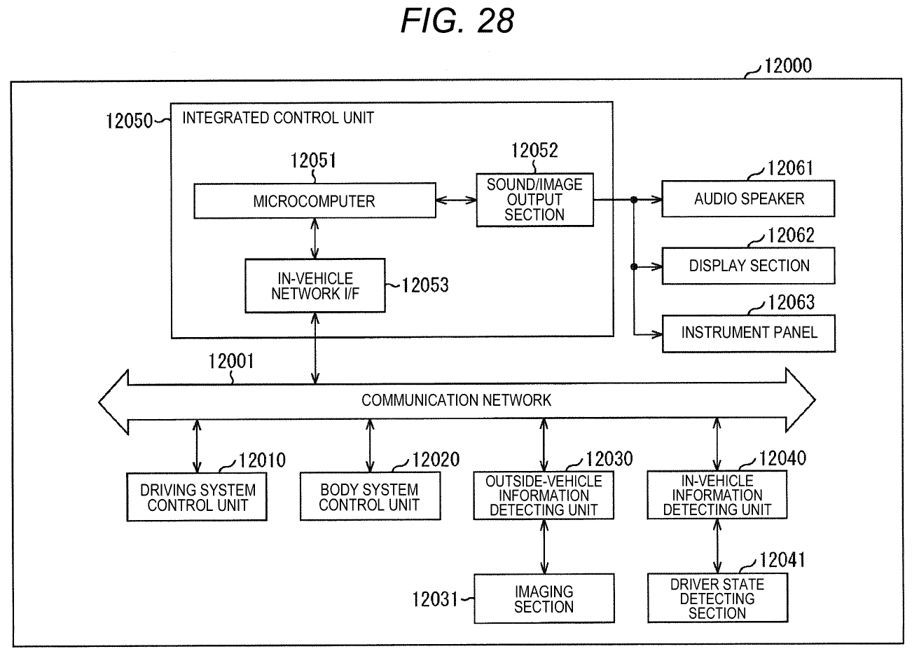

FIG. 28 is a block diagram illustrating a schematic configuration example of a vehicle control system, which is an example of a mobile body control system to which the technology according to the present disclosure can be applied.

The vehicle control system 12000 includes a plurality of electronic control units connected to each other via a communication network 12001. In the example illustrated in FIG. 28, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and an in-vehicle network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating driving force of the vehicle, such as an internal combustion engine or a driving motor, a driving force transmitting mechanism for transmitting the driving force to wheels, a steering mechanism for adjusting a steering angle of the vehicle, a braking device for generating braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, and the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS), the functions including collision avoidance or shock mitigation for the vehicle, following driving based on an inter-vehicle distance, vehicle speed maintaining driving, a warning of collision of the vehicle, a warning of deviation of the vehicle from a lane, or the like.

In addition, the microcomputer 12051 can perform cooperative control intended for, for example, automated driving in which the vehicle travels autonomously without depending on the driver's operation by controlling the driving force generating device, the steering mechanism, the braking device, or the like on the basis of the information about surroundings of the vehicle, the information being acquired by the outside-vehicle information detecting unit 12030 or the in-vehicle information detecting unit 12040.

Furthermore, the microcomputer 12051 can output a control command to the body system control unit 12020 on the basis of the vehicle exterior information acquired by the outside-vehicle information detecting unit 12030. For example, the microcomputer 12051 can perform cooperative control intended to prevent glare such as switching from high beam to low beam by controlling the headlamp in accordance with a position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 28, as the output device, an audio speaker 12061, a display section 12062, and an instrument panel 12063 are illustrated. The display section 12062 may, for example, include at least one of an on-board display and a head-up display.

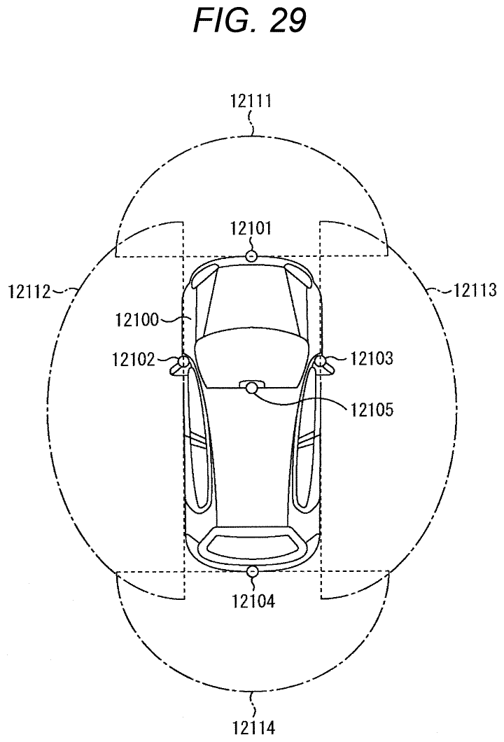

FIG. 29 is a diagram illustrating an example of an installation position of the imaging section 12031.

In FIG. 29, imaging sections 12101, 12102, 12103, 12104, and 12105 are included as the imaging section 12031.

The imaging sections 12101, 12102, 12103, 12104, and 12105 are, for example, provided at positions on a front nose, sideview mirrors, a rear bumper, a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 29 illustrates an example of imaging ranges of the imaging sections 12101 to 12104. An imaging range 12111 represents the imaging range of the imaging section 12101 provided to the front nose, imaging ranges 12112 and 12113 respectively represent the imaging ranges of the imaging sections 12102 and 12103 provided to the sideview mirrors, and an imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Furthermore, the microcomputer 12051 can set an inter-vehicle distance to be secured in advance in front of the preceding vehicle, and can perform automatic brake control (including follow-up stop control), automatic acceleration control (including follow-up start control), and the like. It is thus possible to perform cooperative control intended for, for example, automated driving in which the vehicle travels autonomously without depending on the driver's operation.

For example, on the basis of the distance information obtained from the imaging sections 12101 to 12104, the microcomputer 12051 can classify three-dimensional object data regarding three-dimensional objects into two-wheeled vehicles, standard-sized vehicles, large-sized vehicles, pedestrians, and other three-dimensional objects such as utility poles, extract the three-dimensional object data, and use the three-dimensional object data for automatic avoidance of obstacles. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. In addition, the sound/image output section 12052 may control the display section 12062 so that an icon or the like representing the pedestrian is displayed at a desired position.

An example of the vehicle control system to which the technology according to the present disclosure is applicable has been described above. The technology according to the present disclosure can be applied to the imaging section 12031 and the like in the configuration described above. Specifically, the imaging devices 1, 1A, and 1B can be applied to the imaging section 12031.

### Other Embodiments

As described above, the present disclosure has been described by the embodiments, the modifications, the application examples, and the applied example, but it should not be understood that the description and the drawings forming a part of this disclosure limit the present disclosure. Various alternative embodiments, examples, and operation technologies will be apparent to those skilled in the art from this disclosure. For example, the planar shape of one of the pad openings H11 adjacent to each other and the planar shape of the other one of the pad openings H11 may be the same or may be different. This similarly applies to the pad openings H11A and 11B.

It is a matter of course that the present technology includes various embodiments and the like not described herein. At least one of various omissions, substitutions, or changes of the components may be made without departing from the gist of the above-described embodiments and modifications. In addition, the effects described in the present specification are merely examples and not restrictive, and there may also be other effects.

Note that the present disclosure can also have the following configurations.

(1)

A light detection device including:
a first substrate portion including a pixel region and a peripheral region located around the pixel region; and
a semiconductor chip including a bump electrode, in which
the first substrate portion includes
   a first semiconductor layer,
   a photoelectric conversion section provided in the first semiconductor layer in the pixel region,
   a pad electrode provided in one surface side of the first semiconductor layer in the peripheral region, and
   an insulating film provided in the one surface side of the first semiconductor layer,
the insulating film is provided with a pad opening that opens a portion above the pad electrode, and
the bump electrode is bonded to the pad electrode in a state of being separated from a peripheral edge portion of an opening end of the pad opening.
   (2)

The light detection device according to (1), in which the bump electrode is bonded to the pad electrode in a state of being separated from a side surface of the pad opening.

(3)

The light detection device according to (1) or (2), in which a diameter of the opening end is equal to a diameter of the pad electrode or smaller than the diameter of the pad electrode.

(4)

The light detection device according to (1) or (2), in which the peripheral edge portion of the opening end is flush with a front surface of the pad electrode.

(5)

The light detection device according to (1) or (2), in which a diameter of the opening end is larger than a diameter of the pad electrode.

(6)

The light detection device according to any one of (1), (3), and (5), in which
the pad opening includes
   a first opening including the opening end, and
   a second opening communicating with a bottom portion of the first opening and having the pad electrode as a bottom surface, and
a diameter of the second opening is smaller than a diameter of the first opening.
   (7)

The light detection device according to (6), in which the bump electrode is bonded to the pad electrode in a state of being separated from a side surface of the first opening.

(8)

The light detection device according to (6) or (7), in which
the pad opening includes a recessed portion that is a part of the bottom portion of the first opening and is recessed from a front surface of the insulating film, and
the recessed portion is provided on at least a part of a peripheral edge of the second opening.
   (9)

The light detection device according to (8), in which
when the peripheral edge portion of the opening end is defined as an outer peripheral edge portion, and
an end portion of the recessed portion on a side of the second opening is defined as an inner peripheral edge portion,
a thickness of the inner peripheral edge portion is 1 μm or less.
   (10)

The light detection device according to (8) or (9), in which
when the peripheral edge portion of the opening end is defined as an outer peripheral edge portion, and
an end portion of the recessed portion on a side of the second opening is defined as an inner peripheral edge portion,
a side surface of the inner peripheral edge portion is inclined or curved with respect to a bottom surface of the second opening such that a diameter of the second opening decreases as approaching the bottom surface of the second opening from an opening end of the second opening.
   (11)

The light detection device according to any one of (6) to (10), in which a side surface of the first opening is inclined or curved with respect to a bottom surface of the first opening such that the diameter of the first opening decreases as approaching the bottom surface of the first opening.

(12)

The light detection device according to any one of (6) to (11), in which
in plan view from a thickness direction of the first substrate portion,
the first opening and the second opening have the same shape.
   (13)

The light detection device according to any one of (6) to (11), in which
in plan view from a thickness direction of the first substrate portion,
the first opening and the second opening have different shapes.
   (14)

The light detection device according to any one of (1) to (13), in which
the bump electrode includes an alloy layer constituted by an alloy of tin (Sn) and silver (Ag), and
the alloy layer is bonded to the pad electrode.
   (15)

The light detection device according to any one of (1) to (14), in which
the first substrate portion further includes a wiring provided on the one surface side of the first semiconductor layer in the peripheral region, and
the pad electrode includes
   an electrode film and
   a barrier metal film provided between the electrode film and the wiring.
      (16)

The light detection device according to (15), in which
the electrode film includes a cobalt (Co) film and a copper (Cu) film provided on the cobalt (Co) film, and
the bump electrode is bonded to the copper (Cu) film.

### REFERENCE SIGNS LIST

1, 1A, 1B Imaging device
1a Pixel section
5 Electronic apparatus
10, 10A, 10B Sensor element
11 Silicon substrate
11B Pad opening
11S1 Back surface
11S2, 31a Front surface
12 Photoelectric conversion section
13, 13A1, 13A2, 13A3, 13A4 Through via
20 Multilayer wiring layer
21, 21A, 21B, 21C, 21D, 21E Insulating layer
22, 22A, 22B, 22C, 22D, 33, 63 Wiring
31 Interlayer insulating film
32 Light-shielding film
34, 36 Pad electrode
35 Pixel isolation section
37 Inner lens layer
37L Inner lens
38 Flattening layer
38A Insulating film
39 Pixel isolation section
40 Protective layer
41 Color filter
42 On-chip lens layer
42L On-chip lens
50 Logic chip
51 Alloy layer
52 Ni layer
55 Bump electrode
100A Pixel region
100B Peripheral region
130 Peripheral circuit section
131 Row scanning section
132 System control section
133 Horizontal selection section
134 Column scanning section
135 Horizontal signal line
210 Optical system
211 Shutter device
212 Signal processing section
213 Drive section
311 Recess section
341 Co film
342 Cu film
1206 Display section
12000 Vehicle control system
12001 Communication network
12010 Driving system control unit
12020 Body system control unit
12030 Outside-vehicle information detecting unit
12031 Imaging section
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101, 12102, 12103, 12104, 12105, 12111, 12112, 12113, 12114 Imaging range
AMP Amplification transistor
BM Barrier metal
Dout Video signal
FRG Peripheral edge portion (outer peripheral edge portion)
FRG2 Inner peripheral edge portion
FRG-2, H11c, H111c Side surface
H11, H11A, H11B Pad opening
H12 Opening
H111 First opening
H112 Second opening
I In-vehicle network
IC External control
Lread Pixel drive line
Lsig Vertical signal line
P Unit pixel
PD Photodiode
RST Reset transistor
S Space
SEL Selection transistor
TG Transfer transistor

1. A light detection device comprising:
a first substrate portion including a pixel region and a peripheral region located around the pixel region; and
a semiconductor chip including a bump electrode, wherein
the first substrate portion includes
a first semiconductor layer,
a photoelectric conversion section provided in the first semiconductor layer in the pixel region,
a pad electrode provided in one surface side of the first semiconductor layer in the peripheral region, and
an insulating film provided in the one surface side of the first semiconductor layer,
the insulating film is provided with a pad opening that opens a portion above the pad electrode, and
the bump electrode is bonded to the pad electrode in a state of being separated from a peripheral edge portion of an opening end of the pad opening.

2. The light detection device according to claim 1, wherein the bump electrode is bonded to the pad electrode in a state of being separated from a side surface of the pad opening.

3. The light detection device according to claim 1, wherein a diameter of the opening end is equal to a diameter of the pad electrode or smaller than the diameter of the pad electrode.

4. The light detection device according to claim 1, wherein the peripheral edge portion of the opening end is flush with a front surface of the pad electrode.

5. The light detection device according to claim 1, wherein a diameter of the opening end is larger than a diameter of the pad electrode.

6. The light detection device according to claim 1, wherein
the pad opening includes
a first opening including the opening end, and
a second opening communicating with a bottom portion of the first opening and having the pad electrode as a bottom surface, and
a diameter of the second opening is smaller than a diameter of the first opening.

7. The light detection device according to claim 6, wherein the bump electrode is bonded to the pad electrode in a state of being separated from a side surface of the first opening.

8. The light detection device according to claim 6, wherein
the pad opening includes a recessed portion that is a part of the bottom portion of the first opening and is recessed from a front surface of the insulating film, and
the recessed portion is provided on at least a part of a peripheral edge of the second opening.

9. The light detection device according to claim 8, wherein
when the peripheral edge portion of the opening end is defined as an outer peripheral edge portion and
an end portion of the recessed portion on a side of the second opening is defined as an inner peripheral edge portion,
a thickness of the inner peripheral edge portion is 1 μm or less.

10. The light detection device according to claim 8, wherein
when the peripheral edge portion of the opening end is defined as an outer peripheral edge portion and
an end portion of the recessed portion on a side of the second opening is defined as an inner peripheral edge portion,
a side surface of the inner peripheral edge portion is inclined or curved with respect to a bottom surface of the second opening such that the diameter of the second opening decreases as approaching the bottom surface of the second opening from an opening end of the second opening.

11. The light detection device according to claim 6, wherein a side surface of the first opening is inclined or curved with respect to a bottom surface of the first opening such that the diameter of the first opening decreases as approaching the bottom surface of the first opening.

12. The light detection device according to claim 6, wherein
in plan view from a thickness direction of the first substrate portion,
the first opening and the second opening have the same shape.

13. The light detection device according to claim 6, wherein
in plan view from a thickness direction of the first substrate portion,
the first opening and the second opening have different shapes.

14. The light detection device according to claim 1, wherein
the bump electrode includes an alloy layer constituted by an alloy of tin (Sn) and silver (Ag), and
the alloy layer is bonded to the pad electrode.

15. The light detection device according to claim 1, wherein
the first substrate portion further includes a wiring provided on the one surface side of the first semiconductor layer in the peripheral region, and
the pad electrode includes
an electrode film and
a barrier metal film provided between the electrode film and the wiring.

16. The light detection device according to claim 15, wherein
the electrode film includes a cobalt (Co) film and a copper (Cu) film provided on the cobalt (Co) film, and
the bump electrode is bonded to the copper (Cu) film.
